(19) United States
(12) Patent Application Publication
(10) Pub. No.: US 2024/0234595 A1
(43) Pub. Date: Jul. 11, 2024

(54) OPTICAL ELEMENT DEVICE

(71) Applicant: ROHM CO., LTD., Kyoto (JP)

(72) Inventors: Eiji KUWAHARA, Kyoto (JP); Toru HIGUCHI, Kyoto (JP)

(73) Assignee: ROHM CO., LTD., Kyoto (JP)

(21) Appl. No.: 18/405,192

(22) Filed: Jan. 5, 2024

(30) Foreign Application Priority Data
Jan. 10, 2023 (JP) 2023-001573

(51) Int. Cl. H01L 31/0203; H01L 31/0216; H01L 33/56; H01L 33/62

(52) U.S. Cl. CPC H01L 31/0203; H01L 31/02162; H01L 33/56; H01L 33/62

(57) ABSTRACT

The present disclosure provides an optical element device. The optical element device includes: a semiconductor substrate, having a light receiving unit or a light emitting unit; a transparent sealing resin, sealing the semiconductor substrate; and a convex portion, directly or indirectly connected to the semiconductor substrate. The convex portion is covered by the transparent sealing resin.

### TECHNICAL FIELD

The present disclosure relates to an optical element device.

### BACKGROUND

An optical element device such as an optical device is available in the prior art. For example, the Japan Patent Publication 2021-165671 discloses an optical sensor including a detection unit detecting light, a filter allowing light to pass through, and a sealing resin sealing the detection unit and the filter.

### PRIOR ART DOCUMENT

### Patent publication

[Patent document 1] Japan Patent Publication No. 2021-165671

### BRIEF DESCRIPTION OF THE DRAWINGS

FIG. 1 is a plan view of an optical element device according to a first embodiment.

FIG. 2 is a cross-sectional diagram along a line II-II in FIG. 1.

FIG. 3 is a cross-sectional diagram along a line III-III in FIG. 1.

FIG. 4 is an enlarged partial cross-sectional diagram of a region IV in FIG. 2.

FIG. 5 is an enlarged partial cross-sectional diagram of a variation example of an optical element device according to the first embodiment.

FIG. 6 is an enlarged partial cross-sectional diagram of a variation example of an optical element device according to the first embodiment.

FIG. 7 is an enlarged partial cross-sectional diagram of a variation example of an optical element device according to the first embodiment.

FIG. 8 is a cross-sectional diagram of a variation example of an optical element device according to the first embodiment.

FIG. 9 is a cross-sectional diagram of an optical element device according to a second embodiment.

### DETAILED DESCRIPTION OF THE EMBODIMENTS

Details of embodiments of the present disclosure are described below. Moreover, unless otherwise specified, the same or corresponding parts are denoted by the same reference numerals or symbols in the accompanying drawings below, and related description is omitted.

### <First Embodiment>

### <Configuration of Optical Element Device>

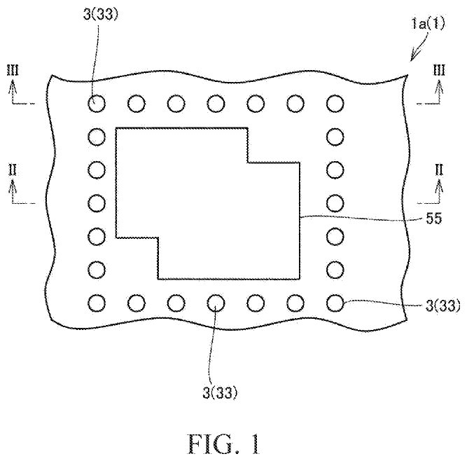

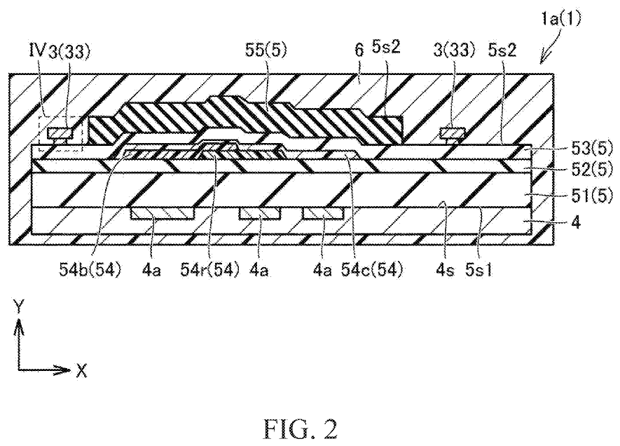

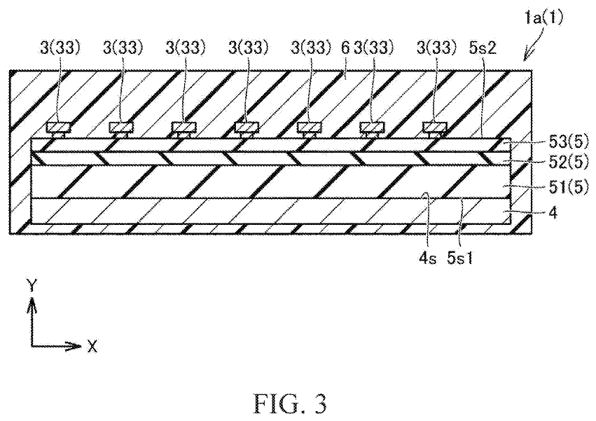

FIG. 1 shows a plan view of an optical element device 1 according to the first embodiment. FIG. 2 shows a cross-sectional diagram along a line II-II in FIG. 1. FIG. 3 shows a cross-sectional diagram along a line III-III in FIG. 1. FIG. 4 shows an enlarged partial cross-sectional diagram of a region IV in FIG. 2.

The optical element device 1 shown in FIG. 1 to FIG. 4 is, for example, an optical sensor 1a that detects light, and primarily includes a semiconductor substrate 4, a coating layer 5 and a transparent sealing resin 6. Moreover, as described below, the optical element device 1 of the present disclosure can also be a light emitting element 1b including a light emitting unit emitting light.

When the optical element device 1 of the first embodiment is implemented by an optical sensor 1a, the coating layer 5 can be formed on the semiconductor substrate 4. The transparent sealing resin 6 seals the semiconductor substrate 4 and the coating layer 5.

The semiconductor substrate 4 is, for example, a Si substrate. The semiconductor substrate 4 has a substrate surface 4s. The substrate surface 4s is an incident surface of light detected by the optical sensor 1a. When the optical element device 1 of the first embodiment is implemented by the optical sensor 1a, the semiconductor substrate 4 has a light receiving unit 4a. The light receiving unit 4a is formed on the substrate surface 4s. As shown in FIG. 1 and FIG. 2, in the substrate surface 4s, a part in which the light receiving unit 4a is formed is a light receiving surface of the optical sensor 1a. The light receiving unit 4a detects light passing through the coating layer 5 and incident on the optical sensor 1a.

The light receiving unit 4a can be formed to be one in quantity, or can be formed to be plural in quantity to match the light detected. For example, three light receiving units 4a can be formed as shown in FIG. 2.

The coating layer 5 has a first laminated portion 55, a protection film portion 53, a color filter portion 54, a second laminated portion 52 and a third laminated portion 51. The coating layer 5 includes the first laminated portion 55, the protection film portion 53, the color filter portion 54, the second laminated portion 52 and the third laminated portion 51 laminated sequentially from top in a Y direction in FIG. 2, for example. That is to say, in a side view of the optical sensor 1a, the first laminated unit 55 in the coating layer 5 is arranged on a position farthest away from the semiconductor substrate 4 in the Y direction. The third laminated portion 51 is connected to the substrate surface 4s, and the third laminated portion 51 in the coating layer 5 is arranged on a position closest to the semiconductor substrate 4 in the Y direction.

The third laminated portion 51 has a first coating layer surface 5s1. The first coating layer surface 5s1 is a surface facing the semiconductor substrate 4. That is to say, the first coating layer surface 5s1 is connected to the substrate surface 4s. The third laminated portion 51 is, for example, an insulating film. The material forming the third laminated portion 51 is, for example, silicon oxide (SiO₂).

As shown in FIG. 2, when viewing from the third laminated portion 51 in the Y direction, the second laminated portion 52 is located opposite to a region in which the semiconductor substrate 4 is arranged. The second laminated portion 52 is, for example, a passivation film. The material forming the second laminated portion 52 is, for example, silicon nitride (SiN).

The color filter portion 54 is connected to the second laminated portion 52. As shown in FIG. 2, when viewing from the second laminated portion 52 in the Y direction, the color filter portion 54 is located opposite to the region in which the semiconductor substrate 4 is arranged. For light within a visible range incident on the optical sensor 1a, the color filter portion 54 allows light within a wavelength range corresponding to a predetermined color to pass through. The color filter portion 54 includes, for example, a transparent filter portion 54c, a red filter portion 54r and a blue filter portion 54b. The transparent filter portion 54c allows light within a wavelength range corresponding to all colors in light within a visible range to pass through. The red filter portion 54r allows light within a wavelength range corresponding to red in light within a visible range to pass through. The blue filter portion 54b allows light within a wavelength range corresponding to blue in light within a visible range to pass through. The color filter portion 54 can also include, for example, a color filter portion that allows light within a wavelength range corresponding to other colors to pass through. The material forming the color filter portion 54 is, for example, an epoxy material.

In in a plan view when viewing the semiconductor substrate 4 from the color filter portion 54, the transparent filter portion 54c, the red filter portion 54r and the blue filter portion 54b are respectively arranged to overlap the light receiving units 4a. As such, light within a wavelength range corresponding to a predetermined color in light within a visible range incident on the optical sensor 1a can be detected in each of the light receiving units 4a.

As shown in FIG. 2, the protection film portion 53 is connected to the second laminated portion 52 to cover the color filter portion 54. When viewing from the second laminated portion 52 in the Y direction, the protection film portion 53 is located opposite to the region in which the semiconductor substrate 4 is arranged. The protection film portion 53 is a film protecting the color filter portion 54. The material forming the protection film portion 53 is, for example, SiO₂.

As shown in FIG. 2, the first laminated portion 55 is connected to the protection film portion 53. When viewing from the protection film portion 53 in the Y direction, the first laminated portion 55 is located opposite to the region in which the semiconductor substrate 4 is arranged. The protection film portion 53 and the first laminated portion 55 have a second coating layer surface 5s2. That is to say, when viewing from the protection film portion 53 in the Y direction, the second coating layer surface 5s2 is a surface of the protection film portion 53 and the first laminated portion 55 located opposite to the first coating layer surface 5s1.

The first laminated portion 55 is formed by laminating a plurality of oxide film layers having different refractive indices to block light in infrared and ultraviolet wavelength ranges. The materials forming the plurality of oxide film layers are appropriately determined according to optical characteristics needed by the first laminated portion 55. As such, the first laminated portion 55 allows light within a visible range in light incident on the optical sensor 1a to pass through, and blocks light within infrared and ultraviolet wavelength ranges.

A part of the first laminated portion 55 is formed on the second coating layer surface 5s2 to overlap the light receiving unit 4a in a plan view when viewing the semiconductor substrate 4 from the first laminated portion 55. As such, the first laminated portion 55 allows light within a visible range incident on the optical sensor 1a to pass through, and the light receiving unit 4a can then detect light within a wavelength range corresponding to a predetermined color.

Moreover, the optical element device 1 of the first embodiment is characterized by including a convex portion 3 covered by the transparent sealing resin 6, as shown in FIG. 1 to FIG. 4. More specifically, as shown in FIG. 2 and FIG. 3, the convex portion 3 is formed on the second coating layer surface 5s2 of the protection film portion 53. The convex portion 3 includes a plurality of convex shaped portions 33. The transparent sealing resin 6 seals the semiconductor substrate 4 and the coating layer 5 to cover the convex portion 3. Due to a difference in coefficients of thermal expansion of the transparent sealing resin 6 and the coating layer 5, there is a concern that the transparent sealing resin 6 maybe stripped off from the coating layer 5. In the event of such stripping off, a gap is produced between the transparent sealing resin 6 and the coating layer 5. As a result, there may be changes in characteristics of light detected in the light receiving unit 4a. In the optical element device 1 of the first embodiment, tightness between the transparent sealing resin 6 and the coating layer 5 is improved by means of providing the convex portion 3 on the coating layer 5. As a result, the transparent sealing resin 6 can be prevented from stripping off from the coating layer 5.

As shown in FIG. 1, in a plan view when viewing the semiconductor substrate 4 from the convex portion 3, the convex portion 3 is arranged along an outer periphery of the first laminated portion 55. That is to say, the plurality of convex shaped portions 33 are arranged at intervals from one another along the outer periphery of the first laminated portion 55 to surround the first laminated portion 55. As shown in FIG. 1 and FIG. 2, a plurality of convex portions 3 can also be arranged on opposite positions across a center of the first laminated portion 55. The convex portion 3 is arranged not to overlap the light receiving unit 4a in a plan view when viewing the semiconductor substrate 4 from the convex portion 3. For example, as shown in FIG. 3, the convex portion 3 is arranged on the second coating layer surface 5s2 of the protection film portion 53 in a region without the first laminated portion 55. As such, the convex portion 3 does not hinder the light incident on the light receiving unit 4a, and the light receiving unit 4a is able to detect the light.

For the perspective of improving the tightness between the transparent sealing resin 6 and the coating layer 5, the plurality of convex shaped portions 33 serving as the protrusion 3 are preferably formed, as shown in FIG. 1. The number of the convex shaped portions 33 can be, for example, 4. The number of the convex shaped portions 33 can also be, for example, 8. The number of the convex shaped portions 33 can further be, for example, 16.

As shown in FIG. 4, the convex portion 3 has a first part 31 and a second part 32. The first part 31 has a first lower surface 31b, a first upper surface 31u and a first side surface 31s. The first lower surface 31b is a surface facing the second coating layer surface 5s2. The first upper surface 31u is a surface opposite to the first lower surface 31b. The first side surface 31s is a surface connecting the first lower surface 31b and the first upper surface 31u. The second part 32 has a second lower surface 32b, a second upper surface 32u and a second side surface 32s. The second lower surface 32b is a surface facing the first upper surface 31u. The second upper surface 32u is a surface opposite to the second lower surface 32b. The second side surface 32s is a surface connecting the second lower surface 32b and the second upper surface 32u. The first part 31 is connected to the second coating layer surface 5s2 on the first lower surface 31b. The second part 32 is connected to the first upper surface 31u of the first part 31 on the second lower surface 32b.

The first upper surface 31u and the first lower surface 31b of the first part 31 are shaped as circular cylinders. The second upper surface 32u and the second lower surface 32b of the second part 32 are shaped as circular cylinders. As shown in FIG. 4, any desired region in the first part 31 in the Y direction is set as a first region A1, and a width W1 of the first region A1 in the X direction is equivalent to a diameter of the cylinder forming the first part 31. Moreover, any desired region in the second part 32 in the Y direction is set as a second region A2, and a width W2 of the second region A2 in the X direction is equivalent to a diameter of the cylinder forming the second part 32.

The width W1 is, for example, different from the width W2. From a different perspective, in the convex portion 3, the width W1 of the first region A1 can also be different from the width W2 of the second region A2. In the Y direction in FIG. 4, the first region A1 is a region in the convex portion 3 on a position away from the second coating layer surface 5s2. In the Y direction in FIG. 4, the second region A2 is a region in the convex portion 3 on a position farther away from the second coating layer surface 5s2 than the first region A1. The first region A1 and the second region A2 are, for example, surfaces in parallel with respect to the second coating layer surface 5s2. As such, in the convex portion 3, a stepped portion is formed in a region between the first region A1 and the second region A2, more specifically, in a part connecting the first part 31 and the second part 32. Thus, a surface area of the convex portion 3 connected to the transparent sealing resin 6 is increased, so that the tightness between the transparent sealing resin 6 and the coating layer 5 is improved.

The width W1 can be greater than the width W2; however, as shown in FIG. 4, the width W1 is preferably less than the width W2. As such, by covering the second lower surface 32b of the second part 32 by the transparent sealing resin 6, the transparent sealing resin 6 can be effectively inhibited from stripping off from a surface of the convex portion 3. Thus, the tightness between the transparent sealing resin 6 and the coating layer 5 is improved.

The convex portion 3 includes at least one main element selected from a group comprising of copper, nickel, gold, aluminum, silver, titanium and tungsten. The material forming the first part 31 is, for example, copper. The material forming the second part 32 is, for example, nickel. A coating layer (not shown) can be disposed on the second upper surface 32u of the second part 32. The material forming the coating layer is, for example, gold. A non-coating layer such as either one of a sputtered layer or evaporated layer can be disposed on the second upper surface 32u of the second part 32. Thus, the convex portion 3 can be formed by laminating two or more materials (for example, two or more metals). When the convex portion 3 is manufactured, if the material forming the second part 32 is preferentially etched before the material forming the first part 31, the convex portion 3 in which the width W1 is less than the width W2 is formed, as shown in FIG. 4.

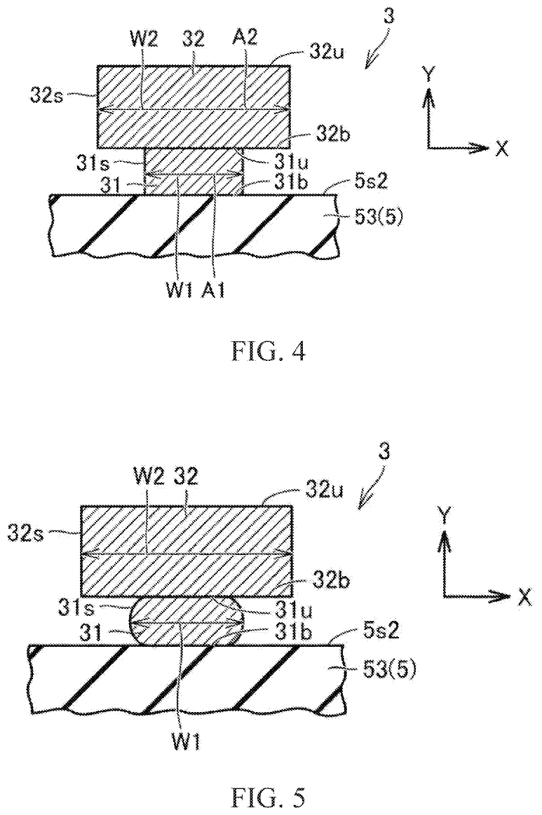

Moreover, as shown in FIG. 5 to FIG. 7, the convex portion 3 can also have a shape different from the shape of the convex portion 3 shown in FIG. 4. FIG. 5 to FIG. 7 show enlarged partial cross-sectional diagrams of variation examples of the convex portion 3 of the optical element device 1 according to the first embodiment. FIG. 5 to FIG. 7 correspond to FIG. 4. The optical element device 1 shown in FIG. 5 to FIG. 7 has basically the same configuration as the optical element device 1 shown in FIG. 1 to FIG. 4, but the convex portion 3 has a different shape.

For example, as shown in FIG. 5, the first side surface 31s of the first part 31 can have a shape different from the shape of the first side surface 31a of the convex portion 3 shown in FIG. 4. More specifically, the width W1 in the X direction at the first upper surface 31u and the first lower surface 31b can be different. As shown in FIG. 5, in the first part 31, the width W1 in the X direction at the first upper surface 31u and the second lower surface 32b can the smallest. When the metal forming the first part 31 is different from the metal forming the second part 32, only the metal forming the first part 31 is etched. For example, by adjusting conditions for the etching, the convex portion 3 having a shape shown in FIG. 5 is formed. As such, a gap is formed at the part connecting the first part 31 and the second part 32, and if the transparent sealing resin 6 is filled at the gap, the tightness between the transparent sealing resin 6 and the coating layer 5 is further improved. Moreover, in the convex portion 3 shown in FIG. 5, a surface area of the first side surface 31s of the first part 31 is greater than a surface area of the first side surface 31s of the convex portion 3 shown in FIG. 4. The reason for the above is that, the shape of a surface in a cross section of the first side surface 31s shown in FIG. 5 is a curved shape. Thus, the surface area of the convex portion 3 in contact with the transparent sealing resin 6 can be greater than the surface area of the convex portion 3 in FIG. 4.

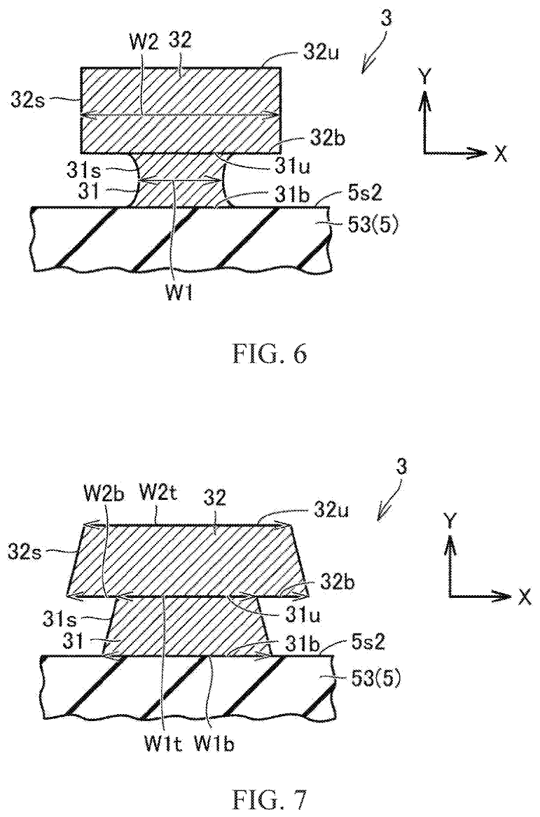

Moreover, as shown in FIG. 6, in the first part 31, the width W1 in the X direction at the first upper surface 31u and the first lower surface 31b can the largest. When the metal forming the first part 31 is different from the metal forming the second part 32, only the metal forming the first part 31 is etched. For example, by adjusting conditions for the etching, the convex portion 3 having a shape shown in FIG. 6 is formed.

Moreover, as shown in FIG. 7, in the first part 31, a width W1t at the first upper surface 31u can be less than a width W1b at the first lower surface 31b. A width W2t at the second upper surface 32u of the second part 32 can also be less than a width W2b at the second lower surface 32b. The convex portion 3 shown in FIG. 7 can be formed by, for example, dry etching. More specifically, the first part 31 having the width W1t at the first upper surface 31u less than the width W1b at the second lower surface 31b is formed by dry etching. Next, a resist film is formed to cover the first side surface 31s and to expose the first upper surface 31u of the first part 31. Next, a metal film to become the second part 32 is formed to cover the first upper surface 31u and the etch-resist film. After a resist film serving as a mask pattern is formed on the metal film, dry etching is performed to form the second part 32. The resist film is removed after that. As such, the convex portion 3 having a shape shown in FIG. 7 is formed.

### <Effects>

The optical element device 1 according to the present disclosure includes the semiconductor substrate 4, the transparent sealing resin 6 and the convex portion 3. The semiconductor substrate 4 has the light receiving unit 4a. The transparent sealing resin 6 seals the semiconductor substrate 4. The convex portion 3 is directly or indirectly connected to the semiconductor substrate 4. The convex portion 3 is covered by the transparent sealing resin 6. As such, the tightness between the transparent sealing resin 6 and the semiconductor substrate 4 can be improved to thereby prevent the transparent sealing resin 6 from stripping off.

The optical element device 1 can further include the coating layer 5. The coating layer 5 covers the light receiving unit 4a. The coating layer 5 has the first coating layer surface 5s1 and the second coating layer surface 5s2. The first coating layer surface 5s1 faces the semiconductor substrate 4. The second coating layer surface 5s2 is located opposite to the first coating layer surface 5s1. The convex portion 3 is formed on the second coating layer surface 5s2. As such, with the convex portion 3 arranged on the coating layer 5, the transparent sealing resin 6 is prevented from stripping off.

With respect to the optical element device 1, in a plan view when viewing the semiconductor substrate 4 from the convex portion 3, the convex portion 3 is arranged not to overlap the light receiving unit 4a. As such, the convex portion 3 does not hinder light incident on the optical sensor 1a. As a result, the light receiving unit 4a is able to detect the light.

With respect to the optical element device 1, the convex portion 3 includes the plurality of convex shaped portions 33. The plurality of convex shaped portions 33 are arranged to surround the light receiving unit 4a in a plan view when viewing the semiconductor substrate 4 from the convex portion 3. As such, the tightness between the transparent sealing resin 6 and the coating layer 5 is improved.

With respect to the optical element device 1, the convex portion 3 includes the first region A1 and the second region A2. The first region A1 is located away from the semiconductor substrate 4. The second region A2 is located farther away from the semiconductor substrate 4 than the first region A1. The second region A2 has the width W2 different form the width W1 of the first region A1. As such, the surface area of the convex portion 3 connected to the transparent sealing resin 6 is increased, so that the tightness between the transparent sealing resin 6 and the coating layer 5 is improved.

With respect to the optical element device 1, the width W2 of the second region A2 is greater than the width W1 of the first region A1. As such, the transparent sealing resin 6 is engaged by the second lower surface 32b of the second part 32, so that the tightness between the transparent sealing resin 6 and the coating layer 5 is further improved.

With respect to the optical element device 1, the convex portion 3 includes at least one main element selected from a group consisting of copper, nickel, gold, aluminum, silver, titanium and tungsten. As such, the convex portion 3 can be formed of any of the materials above.

### <Configurations of Variation Examples>

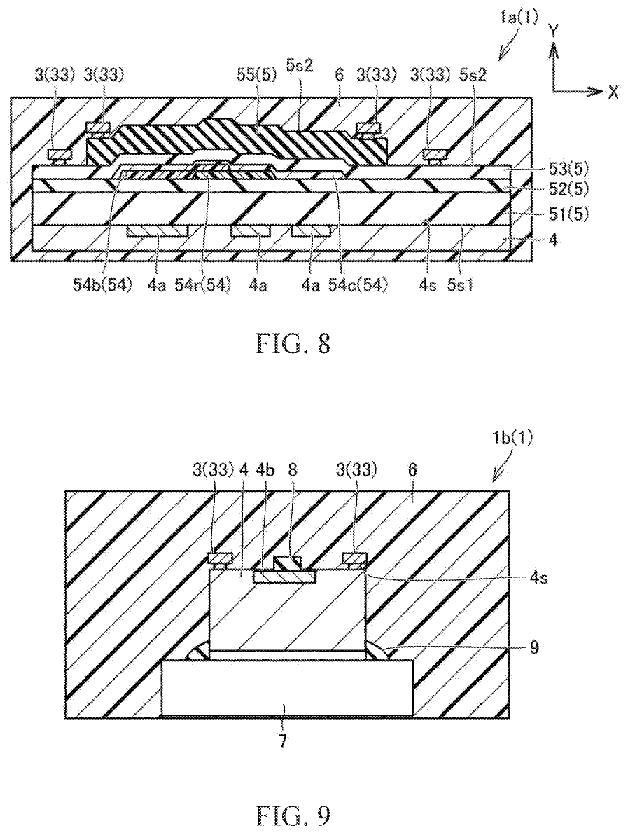

FIG. 8 shows a cross-sectional diagram of a variation example of the optical element device 1 according to the first embodiment. FIG. 8 corresponds to FIG. 2. The optical element device 1 shown in FIG. 8 has basically the same configuration as the optical element device 1 shown in FIG. 1 to FIG. 4, and differs from the optical element device 1 shown in FIG. 1 to FIG. 4 in that, the convex portion 3 is arranged on the first laminated portion 55.

More specifically, as shown in FIG. 8, in addition to being arranged on the second coating layer surface 5s2 which is an upper surface of the protection film portion 53, the convex portion 3 is also arranged on the second coating layer surface 5s2 which is an upper surface of the first laminated portion 55. In a plan view when viewing the semiconductor substrate 4 from the convex portion 3, the convex portion 3 arranged on the first laminated portion 55 is arranged not to overlap the light receiving unit 4a. The convex portion 3 formed on the first laminated portion 55 includes the plurality of convex shaped portions 33. The plurality of convex shaped portions 33 are arranged along an outer periphery of the first laminated portion 55. Moreover, the convex portion 3 arranged on the first laminated portion 55 can also be arranged not to overlap the light receiving unit 4a in the plan view. As such, the tightness between the transparent sealing resin 6 and the first laminated portion 55 is improved.

### <Effects>

With respect to the optical element device 1, the coating layer 5 has the first laminated portion 55 in which a plurality of oxide film layers having different refractive indexes are laminated. A part of the first laminated portion 55 is formed on the second coating layer surface 5s2 to overlap the light receiving unit 4a in a plan view when viewing the semiconductor substrate 4 from the convex portion 3. The convex portion 3 is arranged on the first laminated portion 55. As such, the tightness between the transparent sealing resin 6 and the first laminated portion 55 is improved.

### <Second Embodiment>

### <Configuration of Optical Element Device>

FIG. 9 shows a cross-sectional diagram of an optical element device 1 according to the second embodiment. FIG. 9 corresponds to FIG. 2. The optical element device 1 shown in FIG. 9 has basically the same configuration as the optical element device 1 shown in FIG. 1 to FIG. 4, and differs in that, the optical element device 1 is a light emitting element 1b that emits light but is not the optical sensor 1a. More specifically, as shown in FIG. 9, the semiconductor substrate 4 has a light emitting unit 4b. The light emitting unit 4b is formed on the substrate surface 4s. The convex portion 3 is arranged on the substrate surface 4s. The convex portion 3 includes the plurality of convex shaped portions 33. The plurality of convex shaped portions 33 are arranged to surround the light emitting units 4b. Moreover, a coating layer can also be formed in a region not overlapping the light emitting unit 4b on the substrate surface 4s, or the convex portion 3 can be formed on the coating layer. The coating layer can also be formed on a position overlapping the light emitting unit 4b. That is to say, the optical element device 1 can further include the coating layer. The coating layer can cover the light emitting unit 4b. The coating layer has a first coating layer surface and a second coating layer surface. The first coating layer surface can face the semiconductor substrate 4. The second coating layer surface can be located opposite to the first coating layer surface. The convex portion 3 can be formed on the second coating layer surface. The coating layer can have a first laminated portion in which a plurality of oxide film layers having different refractive indexes are laminated. A part of the first laminated portion can also be formed on the second coating layer surface to overlap the light emitting unit 4b. The convex portion 3 can be arranged on the first laminated portion.

An electrode 8 can be formed on the substrate surface 4s. The electrode 8 can be arranged to overlap the light emitting unit 4b in the plan view when viewing the semiconductor substrate 4 from the convex portion 3. The light emitting unit 1b can radiate light emitted from the light emitting unit 4b from the substrate surface 4s.

The semiconductor substrate 4 is mounted on a support body 7 capable of being mounted with the semiconductor substrate 4. The semiconductor substrate 4 is connected to the support body 7 on a surface located opposite to the substrate surface 4s. The semiconductor substrate 4 and the support body 7 can also be bonded to each other by a die bonding material 9.

The transparent sealing resin 6 seals the support body 7, the semiconductor substrate 4 and the convex portion 3. As such, even if the optical element device 1 is the light emitting element 1b having the light emitting unit 4b, the tightness between the transparent sealing resin 6 and the semiconductor substrate 4 can also be improved as the first embodiment, thereby preventing the transparent sealing resin 6 from stripping off.

### <Effects>

The optical element device 1 according to the present disclosure includes the semiconductor substrate 4, the transparent sealing resin 6 and the convex portion 3. The semiconductor substrate 4 has the light emitting unit 4b. The transparent sealing resin 6 seals the semiconductor substrate 4. The convex portion 3 is directly or indirectly connected to the semiconductor substrate 4. The convex portion 3 is covered by the transparent sealing resin 6. With respect to the optical element device 1, the semiconductor substrate 4 has the substrate surface 4s. The light emitting unit 4b is formed on the substrate surface 4s. The convex portion 3 is arranged on the substrate surface 4s. As such, even if the optical element device 1 is the light emitting element 1b having the light emitting unit 4b, the tightness between the transparent sealing resin 6 and the semiconductor substrate 4 can also be improved to thereby prevent the transparent sealing resin 6 from stripping off.

It should be understood that all aspects of the disclosed embodiments of the present disclosure are illustrative rather than restrictive. Given that no contradictions are incurred, at least two of the disclosed embodiments above can be combined. The basic scope of the present disclosure is described and represented by way of the claims instead of the description above, and is intended to cover all equivalent meanings and variations made within the scope in accordance with the claims.

Various forms of the present disclosure are summarized in the notes below.

### (Note 1)

An optical element device, comprising:
a semiconductor substrate, having a light receiving unit or a light emitting unit;
a transparent sealing resin, sealing the semiconductor substrate; and
a convex portion, directly or indirectly connected to the semiconductor substrate, wherein the convex portion is covered by the transparent sealing resin.

### (Note 2)

The optical element device according to Note 1, wherein
the semiconductor substrate has a substrate surface on which the light receiving unit or the light emitting unit is formed, and
the convex portion is arranged on the substrate surface.

### (Note 3)

The optical element device according to Note 1, further comprising:
a coating layer, covering the light receiving unit or the light emitting unit, wherein
the coating layer has a first coating layer surface facing to the semiconductor substrate and a second coating layer surface disposed opposite to the first coating layer surface, and
the convex portion is formed on the second coating layer surface.

### (Note 4)

The optical element device according to Note 3, wherein
the coating layer has a first laminated portion in which a plurality of oxide film layers having different refractive indexes are laminated,
a part of the first laminated portion is formed on the second coating layer surface to overlap the light receiving unit or the light emitting unit in a plan view when viewing the semiconductor substrate from the convex portion, and
the convex portion is arranged on the first laminated portion.

### (Note 5)

The optical element device according to any one of Notes 1 to 4, wherein in a plan view when viewing the semiconductor substrate from the convex portion, the convex portion is arranged not to overlap the light receiving unit or the light emitting unit.

### (Note 6)

The optical element device according to Note 5, wherein
the convex portion includes a plurality of convex shaped portions, and
in the plan view, the plurality of convex shaped portions are arranged to surround the light receiving unit or the light emitting unit.

### (Note 7)

The optical element device according to any one of Notes 1 to 4, wherein the convex portion includes:
a first region, disposed away from the semiconductor substrate; and
a second region, disposed further from the semiconductor substrate than the first region and having a width different from a width of the first region.

### (Note 8)

The optical element device according to Note 7, wherein the width of the second region is greater than the width of the first region.

### (Note 9)

The optical element device according to any one of Notes 1 to 4, wherein the convex portion includes at least one main element selected from a group comprising copper, nickel, gold, aluminum, silver, titanium and tungsten.

1. An optical element device, comprising:
a semiconductor substrate, having a light receiving unit or a light emitting unit;
a transparent sealing resin, sealing the semiconductor substrate; and
a convex portion, directly or indirectly connected to the semiconductor substrate, wherein
the convex portion is covered by the transparent sealing resin.

2. The optical element device of claim 1, wherein
the semiconductor substrate has a substrate surface on which the light receiving unit or the light emitting unit is formed, and
the convex portion is arranged on the substrate surface.

3. The optical element device of claim 1, further comprising:
a coating layer, covering the light receiving unit or the light emitting unit, wherein
the coating layer has a first coating layer surface facing to the semiconductor substrate and a second coating layer surface disposed opposite to the first coating layer surface, and
the convex portion is formed on the second coating layer surface.

4. The optical element device of claim 3, wherein
the coating layer has a first laminated portion in which a plurality of oxide film layers having different refractive indexes are laminated,
a part of the first laminated portion is formed on the second coating layer surface to overlap the light receiving unit or the light emitting unit in a plan view when viewing the semiconductor substrate from the convex portion, and
the convex portion is arranged on the first laminated portion.

5. The optical element device of claim 1, wherein in a plan view when viewing the semiconductor substrate from the convex portion, the convex portion is arranged not to overlap the light receiving unit or the light emitting unit.

6. The optical element device of claim 2, wherein in a plan view when viewing the semiconductor substrate from the convex portion, the convex portion is arranged not to overlap the light receiving unit or the light emitting unit.

7. The optical element device of claim 3, wherein in a plan view when viewing the semiconductor substrate from the convex portion, the convex portion is arranged not to overlap the light receiving unit or the light emitting unit.

8. The optical element device of claim 4, wherein in a plan view when viewing the semiconductor substrate from the convex portion, the convex portion is arranged not to overlap the light receiving unit or the light emitting unit.

9. The optical element device of claim 5, wherein
the convex portion includes a plurality of convex shaped portions, and
in the plan view, the plurality of convex shaped portions are arranged to surround the light receiving unit or the light emitting unit.

10. The optical element device of claim 6, wherein
the convex portion includes a plurality of convex shaped portions, and
in the plan view, the plurality of convex shaped portions are arranged to surround the light receiving unit or the light emitting unit.

11. The optical element device of claim 1, wherein the convex portion includes:
a first region, disposed away from the semiconductor substrate; and
a second region, disposed further from the semiconductor substrate than the first region and having a width different from a width of the first region.

12. The optical element device of claim 2, wherein the convex portion includes:
a first region, disposed away from the semiconductor substrate; and
a second region, disposed further from the semiconductor substrate than the first region and having a width different from a width of the first region.

13. The optical element device of claim 3, wherein the convex portion includes:
a first region, disposed away from the semiconductor substrate; and
a second region, disposed further from the semiconductor substrate than the first region and having a width different from a width of the first region.

14. The optical element device of claim 4, wherein the convex portion includes:
a first region, disposed away from the semiconductor substrate; and
a second region, disposed further from the semiconductor substrate than the first region and having a width different from a width of the first region.

15. The optical element device of claim 11, wherein the width of the second region is greater than the width of the first region.

16. The optical element device of claim 12, wherein the width of the second region is greater than the width of the first region.

17. The optical element device of claim 1, wherein the convex portion includes at least one main element selected from a group comprising copper, nickel, gold, aluminum, silver, titanium and tungsten.

18. The optical element device of claim 2, wherein the convex portion includes at least one main element selected from a group comprising copper, nickel, gold, aluminum, silver, titanium and tungsten.

19. The optical element device of claim 3, wherein the convex portion includes at least one main element selected from a group comprising copper, nickel, gold, aluminum, silver, titanium and tungsten.

20. The optical element device of claim 4, wherein the convex portion includes at least one main element selected from a group comprising copper, nickel, gold, aluminum, silver, titanium and tungsten.
